(19) United States
(12) Patent Application Publication
(10) Pub. No.: US 2026/0305408 A1
(43) Pub. Date: Oct. 1, 2026

(54) EMBEDDED VERTICAL STRIPS FOR THROUGH SUBSTRATE ELECTRICAL ROUTING

(71) Applicant: Intel Corporation, Santa Clara, CA (US)

(72) Inventors: Bharath V, Bengaluru (IN); Ranjul BALAKRISHNAN, Bangalore (IN); Sandesh Geejagaaru KRISHNAMURTHY, Vajarahalli (IN); Telesphor KAMGAING, Chandler, AZ (US)

(21) Appl. No.: 19/092,830

(22) Filed: Mar. 27, 2025

(51) Int. Cl. H01L 23/498; H01L 23/00; H01L 23/14

(52) U.S. Cl. CPC H10W 70/65; H10W 70/685; H10W 70/695; H10W 90/701; H10W 70/60; H10W 90/724

(57) ABSTRACT

Embodiments disclosed herein include an apparatus that comprises a substrate with a slot through the substrate. In an embodiment, a length of the slot is greater than a width of the slot. In an embodiment, the apparatus further comprises a trace on a sidewall of the slot, and a plug in the slot. In an embodiment, the plug contacts the trace and the sidewall of the slot.

### BACKGROUND

The primary method for establishing connections across layers in a multi-layer package stack-up is through vias. Micro-vias are used across buildup layers, and plated through holes (PTH) are used to provide electrical connections through the core of the package stack-up. However, the geometries of the PTHs can lead to impedance discontinuities and crosstalk due to the size of the copper pads and poor return paths due to close proximities between features.

The sub-optimal geometries of PTHs are due in part to the manufacturing processes used to form the PTHs. In organic core substrates, mechanical drilling is often used to form the openings. In glass core substrates, laser drilling or laser assisted etching is used to form the openings. The thicker core layers in combination with the mechanical and/or laser processing results in larger openings compared to micro vias. Instead of filling the entire volume of the opening with copper (which would be a time consuming process), just the sidewalls of the opening are plated.

### BRIEF DESCRIPTION OF THE DRAWINGS

FIG. 1A is a plan view illustration of a slot formed through a package substrate, in accordance with an embodiment.

FIG. 1B is a plan view illustration of the slot after the sidewalls are plated, in accordance with an embodiment.

FIG. 1C is a plan view illustration of the slot with drill locations shown, in accordance with an embodiment.

FIG. 1D is a plan view illustration of the slot after segmentation drilling is implemented to define individual vertical traces along sidewalls of the slot, in accordance with an embodiment.

FIG. 1E is a plan view illustration of the slot after pads are formed adjacent to the vertical traces, in accordance with an embodiment.

FIG. 2 is a flow diagram that describes a process for forming vertical traces along sidewalls of a slot through a substrate, in accordance with an embodiment.

FIGS. 3A and 3B are plan view illustrations that depict an alternative segmentation drilling process, in accordance with an embodiment.

FIG. 4A is a zoomed in plan view illustration of vertical traces with a trapezoidal shape, in accordance with an embodiment.

FIG. 4B is a zoomed in plan view illustration of vertical traces with a rectangular shape, in accordance with an embodiment.

FIG. 4C is a perspective view illustration of a vertical trace with a trapezoidal cross-sectional shape, in accordance with an embodiment.

FIG. 4D is a perspective view illustration of a vertical trace with a rectangular cross-sectional shape, in accordance with an embodiment.

FIG. 5 is a cross-sectional illustration of an electronic package with a core that includes vertical traces formed with a segmentation process, in accordance with an embodiment.

FIG. 6 is a schematic of a computing device built in accordance with an embodiment.

### EMBODIMENTS OF THE PRESENT DISCLOSURE

Described herein are vertical traces that are embedded in a package substrate to provide improved electrical impedance characteristics for electrical routing in the package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, traditional plated through hole (PTH) architectures that are formed through package cores can cause impedance discontinuities that lead to poor electrical performance. This can lead to lower data transfer rates, increased energy usage, and/or other inefficiencies. Accordingly, embodiments disclosed herein may include an alternative through core electrical routing approach. For example, instead of forming cylindrical vias along the sidewalls of via openings, vertical traces are formed along the sidewalls of openings through the core. In one embodiment, an elongated slot is formed through the core. The sidewalls of the slot are plated, and the plated layer is then segmented into individual vertical traces. The segmentation process may include an additional drilling process, a laser process, an etching process, and/or the like. The vertical traces can be designed so that impedance mismatches are reduced or even eliminated. Further, vertical trace configurations such as those described herein may allow for increased routing density since the vertical traces can be spaced closer to each other than PTH designs.

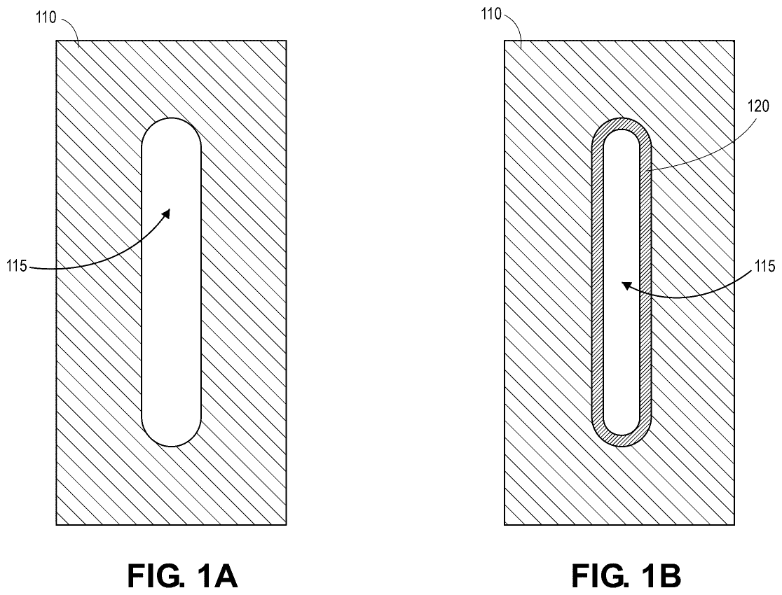

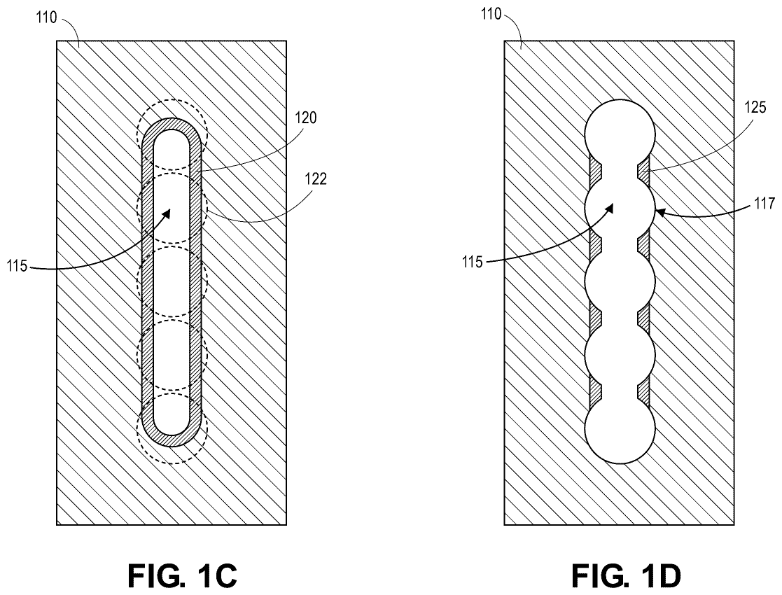

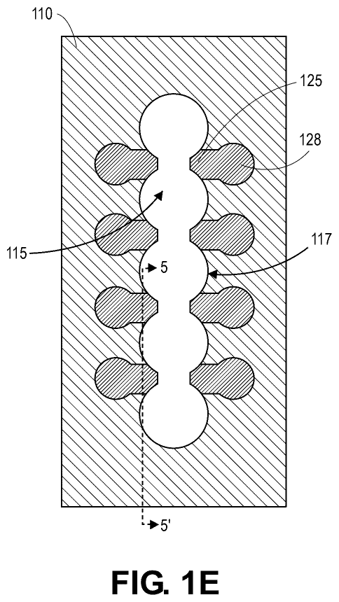

Referring now to FIG. 1A-1E, a series of plan view illustrations that depict a process for forming vertical traces through a core is shown, in accordance with an embodiment. As will be shown, the process to form the vertical traces does not need any new manufacturing systems, additional masking, or the like. As such, the vertical traces may be formed with an economical process.

Referring now to FIG. 1A, a plan view illustration of a substrate 110 with a slot 115 formed through the substrate 110 is shown, in accordance with an embodiment. In an embodiment, the substrate 110 may be any type of material layer used in an electronic package stack-up. For example, the substrate 110 may be the core of a package substrate. The substrate 110 may be an organic core. For example, organic dielectric material with glass fiber reinforcement may be used for the substrate 110. In other embodiments, the substrate 110 may be a glass core. A glass core may comprise a substantially monolithic layer of glass. The glass may comprise any suitable glass material and may include any desired thickness.

In an embodiment, the slot 115 may be a hole that passes through a thickness of the substrate 110. The slot 115 may be formed with any suitable subtractive patterning process. In some embodiments, a mechanical drilling process or a laser drilling process may be used to form the slot 115. In the case of a glass core substrate 110, a laser assisted patterning process may be used to form the slot 115. A laser assisted etching process may include a laser exposure of the substrate 110 that is followed by an etching process that selectively removes the laser exposed region of the substrate 110. The slot 115 may have any suitable shape. For example, the slot 115 in FIG. 1A includes a width that is narrower than a length of the slot 115. The ends of the slot 115 may be rounded in some embodiments. Though, in other embodiments, the ends of the slot 115 may be linear. That is, the slot 115 may have a substantially rectangular shape. In some embodiments, the sidewalls of the slot 115 may be substantially vertical (e.g., when a mechanical drilling process is used to form the slot 115), or the sidewalls of the slot 115 may have a slope (e.g., when a laser drilling or a laser assisted etching process is used to form the slot 115).

Referring now to FIG. 1B, a plan view illustration of the substrate 110 after a liner 120 is plated along sidewalls of the slot 115 is shown, in accordance with an embodiment. In an embodiment, the liner 120 may comprise an electrically conductive material, such as copper or the like. In an embodiment, the liner 120 may be plated with an electrolytic plating process or the like. For example, a seed layer (not shown) may be deposited over the sidewalls of the slot 115, and the liner 120 may be plated up from the seed layer. As shown, the plating of the liner 120 does not fill an entire volume of the slot 115. The liner 120 may comprise copper, an alloy of copper, or any other suitable electrically conductive material.

Referring now to FIG. 1C, a plan view illustration of the substrate 110 with the outline of segmentation regions 122 over the liner 120 is shown, in accordance with an embodiment. In an embodiment, the segmentation regions 122 include a plurality of circular sections. For example, the circular sections may correspond to the size of a drill bit that can be passed through the substrate 110 and the liner 120 with a drilling process. In the illustrated embodiment, the segmentation regions 122 are each the same size and shape. Though, in other embodiments the segmentation regions 122 may have any desired shape and/or size.

Referring now to FIG. 1D, a plan view illustration of the substrate 110 after the liner 120 is segmented to form a plurality of vertical traces 125 is shown, in accordance with an embodiment. As shown, the portions of the substrate 110 and liner 120 that are within the segmentation regions 122 are removed. This may result in portions of the slot 115 being extended in order to electrically isolate each of the vertical traces 125 from each other. For example, surfaces 117 of the slot 115 may now extend into the substrate 110 beyond the original sidewall of the slot 115. When a drilling process is used for the segmentation, the slot 115 surfaces 117 may be curved.

As shown, a plurality of vertical traces 125 are now provided on opposite sides of the slot 115 between the surfaces 117. Due to the drilling process, the vertical traces 125 may have a unique profile. For example, the vertical traces 125 may have a trapezoidal-like shape. A trapezoidal-like shape may refer to a shape that is a trapezoid or is similar to a trapezoid (e.g., including opposing parallel surfaces of different lengths that are connected to each other by opposing non-parallel surfaces). In some embodiments disclosed herein, the non-parallel surfaces may be curved surfaces. That is, the vertical traces 125 may have a shape (as viewed in the plane of FIG. 1D) that is substantially non-rectangular. Though, as will be described in greater detail herein, the vertical traces 125 may also be substantially rectangular in some embodiments.

In an embodiment, the smaller geometry of the vertical traces 125 (as compared to a traditional PTH liner) produces a cross-sectional shape that more closely resembles a standard trace rather than a drilled hole. This conductor profile leads to an increased impedance for the net compared to a PTH liner. Additionally, the vertical traces 125 offer improved signal-to-Vss reference. This contributes to enhanced signal integrity for the package. With this approach, passing electrical signals across the core substrate 110 becomes seamless, and concerns about impedance discrepancies and heightened crosstalk are mitigated. Accordingly, embodiments disclosed herein provide a cost effective solution for providing additional operating margin in the case of high-speed signals.

While a drilling process is described as the segmentation process in FIG. 1D, it is to be appreciated that other subtractive processes may also be used to segment the liner 120. For example, laser ablation, etching, and/or the like may be used to remove portions of the liner 120 in order to provide electrically isolated vertical traces 125.

Referring now to FIG. 1E, a plan view illustration of the substrate 110 after pads 128 are coupled to the vertical traces 125 is shown, in accordance with an embodiment. In an embodiment, the pads 128 may be formed with a plating process or the like. While the pads 128 are proximate to the vertical traces 125, embodiments may also comprise vertical traces 125 that are electrically connected to pads 128 by traces that extend away from the slot 115. Such electrical routing may allow for more flexibility in the routing of signals through the substrate 110.

In the illustrated embodiment, eight vertical traces 125 are shown. Though, it is to be appreciated that any number of vertical traces 125 may be used in accordance with embodiments disclosed herein. That is, any number of vertical traces 125 can be chosen to meet design goals. Additionally, the utilization of the vertical traces 125 can be tailored to suit different needs. For example, in high-speed IO scenarios, alternating vertical traces 125 may be used for ground and signal configurations in order to mitigate crosstalk. Conversely, in low-speed IO applications, all vertical traces 125 may be utilized for signal transmission.

In the illustrated embodiment, the slot 115 is shown as being unfilled. However, embodiments may include filling the remaining volume of the slot 115 with a plug or the like. For example, an organic dielectric material (e.g., buildup film or the like) may fill the slot 115 during the lamination of layers over and/or under the substrate 110 in subsequent manufacturing processes.

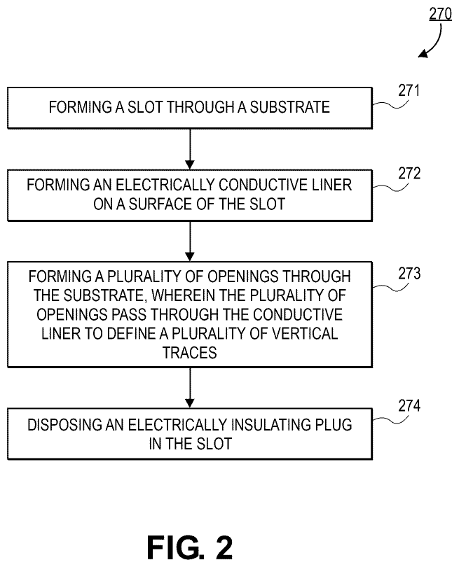

Referring now to FIG. 2, a flow diagram that depicts a process 270 for forming vertical traces through a substrate is shown, in accordance with an embodiment. In an embodiment, the process 270 may be similar to the process described above with respect to FIG. 1A-1E or any other process described in greater detail herein. In an embodiment, the process 270 may begin with operation 271, which comprises forming a slot through a substrate. In an embodiment, the substrate may be a core for a package substrate, such as an organic core, a glass core, or the like. In an embodiment, the slot may be a hole that passes through a thickness of the substrate. The slot may have an elongated shape where a length of the slot is greater than a width of the slot. The slot may be formed with any suitable subtractive process, such as mechanical drilling, laser drilling, etching, or the like.

In an embodiment, the process 270 may continue with operation 272, which comprises forming an electrically conductive liner on a surface of the slot. In an embodiment, the liner may be formed along sidewalls of the slot. The liner may be formed with a plating process, such as an electrolytic plating process. For example a seed layer (e.g., an electroless seed layer) may be formed on the sidewalls of the slot, and the liner may be plated up from the seed layer. The liner may comprise any suitable electrically conductive material, such as copper, an alloy of copper, or the like.

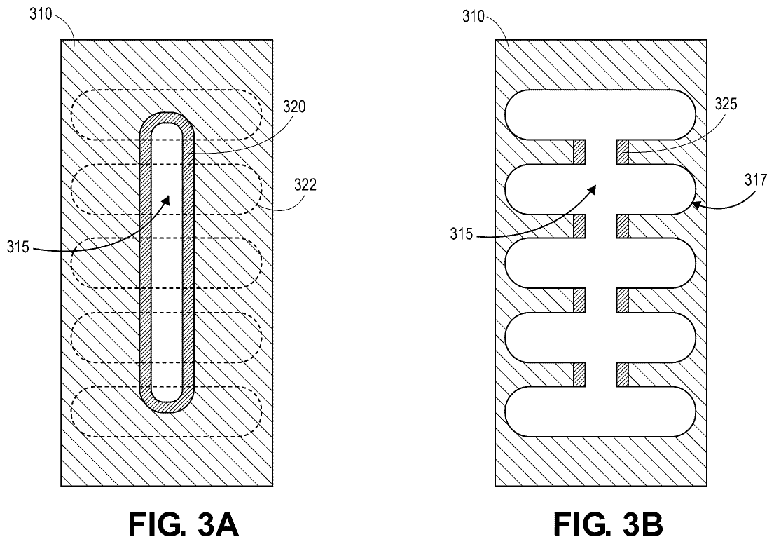

In an embodiment, the process 270 may continue with operation 273, which comprises forming a plurality of openings through the substrate. In an embodiment, the plurality of openings may pass through the conductive liner to define a plurality of vertical traces. In an embodiment, the plurality of openings may be formed with a drilling process, a laser ablation process, an etching process, or the like. The openings may be circular holes (e.g., similar to FIG. 1C) or elongated holes (e.g., similar to FIG. 3A, which will be described in greater detail herein), or the like.

In an embodiment, the process 270 may continue with operation 274, which comprises disposing an electrically insulating plug in the slot. In an embodiment, the plug may be an organic dielectric material or the like. For example, the plug may comprise a buildup film or similar type of material. The plug may be disposed in the slot during a lamination process used to apply a layer over the substrate. For example, a dielectric routing layer may be applied over a core during the assembly of a package substrate.

Referring now to FIGS. 3A and 3B, a pair of plan view illustrations that depict a segmentation process for a liner 320 on the sidewalls of a slot 315 that passes through a thickness of a substrate 310 is shown, in accordance with an embodiment. In FIG. 3A, an outline of segmentation regions 322 over the liner 320 is shown, in accordance with an embodiment. In an embodiment, the segmentation regions 322 include a plurality of slots that are oriented substantially orthogonally to the slot 315. For example, the dimensions of the segmentation regions 322 may correspond to the size of a drill bit that can be passed across the substrate 310 and the liner 320 with a drilling process. In the illustrated embodiment, the segmentation regions 322 are each the same size and shape. Though, in other embodiments the segmentation regions 322 may have any desired shape and/or size.

Referring now to FIG. 3B, a plan view illustration of the substrate 310 after the liner 320 is segmented to form a plurality of vertical traces 325 is shown, in accordance with an embodiment. As shown, the portions of the substrate 310 and liner 320 that are within the segmentation regions 322 are removed. This may result in portions of the slot 315 being extended in order to electrically isolate each of the vertical traces 325 from each other. For example, surfaces 317 of the slot 315 may now extend into the substrate 310 beyond the original sidewall of the slot 315.

As shown, a plurality of vertical traces 325 are now provided on opposite sides of the slot 315 between the surfaces 317. Due to the drilling process, the vertical traces 325 may have a substantially rectangular shape (in the view of FIG. 3B). The vertical traces 325 may be provided at ends of peninsulas of the substrate 310 that are defined by the surfaces 317 that extend into the substrate beyond the original sidewall of the slot 315. As such, each edge of the slot 315 may have a comb-like shape with the vertical traces 325 positioned at ends of each of the prongs of substrate 310 that form the comb-like shape.

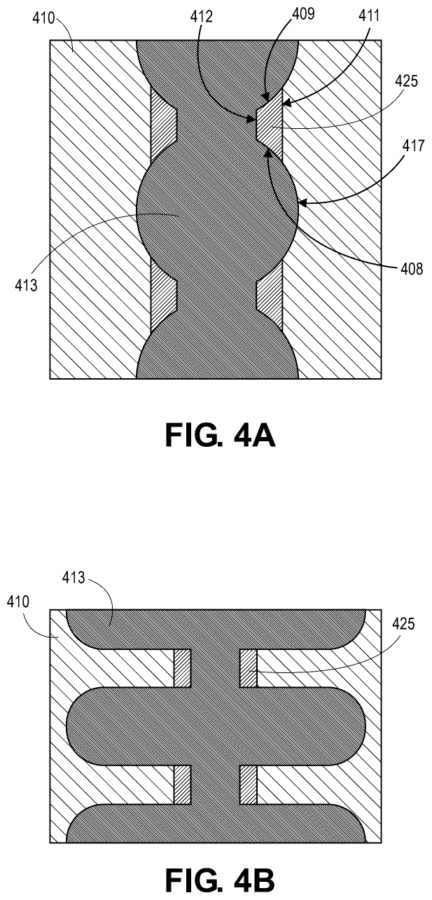

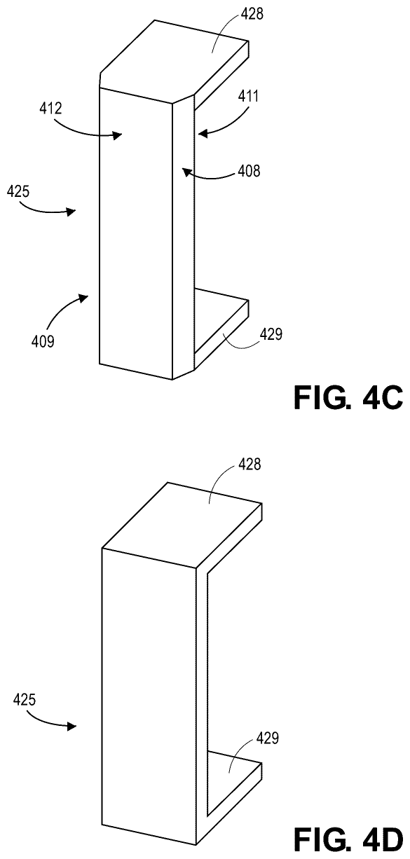

Referring now to FIGS. 4A and 4B, a pair of plan view illustrations that illustrate the shape of the vertical traces in more detail is shown, in accordance with an embodiment. FIG. 4A illustrates a zoomed in plan view of vertical traces 425 that are formed with circular segmentation similar to FIG. 1D, and FIG. 4B illustrates a zoomed in plan view of vertical traces 425 that are formed with a rectangular segmentation similar to FIG. 3B.

As shown in FIG. 4A, the slot through the substrate 410 is filled with a plug 413, and vertical traces 425 may be provided on the sidewalls of the slot between extensions 417. In an embodiment, the vertical traces 425 may have trapezoidal-like shapes. For example, the first surface 411 and the second surface 412 may be parallel to each other with the first surface 411 being wider than the second surface 412. The opposing third surface 408 and fourth surface 409 may be non-parallel. Further, the third surface 408 and the fourth surface 409 may be curved due to the shape of the drill used for the segmentation process. As shown, the plug 413 may contact surfaces of the vertical traces 425 and surfaces of the substrate 410, such as the extensions 417. For example, the plug 413 may contact the second surface 412 of the vertical traces 425, the third surface 408 of the vertical traces 425, the fourth surface 409 of the vertical traces 425, and the extensions 417 of the substrate 410.

In some embodiments, the radius of curvature of the third surface 408 and/or the fourth surface 409 may be the same as a radius of curvature of the extensions 417. Additionally, the third surface 408 and the adjacent extension 417 may be coincident with a single circle (e.g., the circle defined by the drill used in the segmentation process). That is, there may be a substantially smooth transition (e.g., a continuous transition) between the third surface 408 and the adjacent extension 417.

In an embodiment, the segmentation process may also result in vertical traces 425 that are aligned with each other. For example, a first vertical trace on the right side of the slot may be aligned with a second vertical trace on the left side of the slot. In some embodiments, the first vertical trace may be a mirror image of the second vertical trace about a longitudinal centerline across a length of the slot. In some embodiments, a number of vertical traces 425 may be an even number when such a segmentation process is used. Though, it is to be appreciated that alternative segmentation processes (e.g., laser ablation, etching, etc.) may enable the generation of an odd number of vertical traces within a single slot. Further, when alternative segmentation processes are used, the alignment between vertical traces 425 on opposite sides of the slot may not be as perfect as shown in FIG. 4A.

Referring now to FIG. 4B, a cross-sectional illustration of vertical traces 425 that are formed with an elongated segmentation process is shown, in accordance with an embodiment. In an embodiment, the elongated segmentations process may include holes that are slot-like and that traverse the slot in a substantially orthogonal manner. As such, the vertical traces 425 may have substantially rectangular shapes when viewed in a cross-section parallel to the plane shown in FIG. 4B. Further, the vertical traces 425 may be provided at the end of well-defined peninsulas of the substrate 410. In an embodiment, a width of the vertical traces 425 may be substantially equal to a width of the peninsulas of the substrate 410 that contacts the vertical trace. In an embodiment, the plug 413 may fill the slot and surround surfaces of the vertical traces 425 that are not contacting the substrate 410. That is, the plug 413 may directly contact the vertical traces 425 and the substrate 410.

Similar to the embodiment shown in FIG. 4A, the segmentation process may also result in vertical traces 425 that are aligned with each other. For example, a first vertical trace on the right side of the slot may be aligned with a second vertical trace on the left side of the slot. In some embodiments, the first vertical trace may be a mirror image of the second vertical trace about a longitudinal centerline across a length of the slot.

Referring now to FIG. 4C, a perspective view illustration of a vertical trace 425 with a pad 428 at a top of the vertical trace 425 and a pad 429 at a bottom of the vertical trace 425 is shown, in accordance with an embodiment. In an embodiment, the vertical trace 425 is shown without the surrounding substrate and/or plug for clarity. As shown, the vertical trace 425 may have a trapezoidal-like cross-section in a plane orthogonal to the vertical direction of FIG. 4C. That is, surfaces 408 and 409 of the vertical trace 425 may not be orthogonal to surfaces 411 and 412 of the vertical trace 425. In some embodiments, the surfaces 408 and 409 may be curved, similar to other embodiments described in greater detail herein.

In an embodiment, the pads 428 and 429 may extend away from the vertical trace 425. That is, and edge of the pads 428 and 429 may be aligned with an edge of the trace 425. In some embodiments, the pads 428 and 429 extend the same direction away from the vertical trace 425. For example, the pads 428 and 429 may both extend over the substrate (not visible in FIG. 4C). The combination of the pads 428, 429, and the vertical trace 425 may form a roughly C-shaped structure around a portion of the substrate. In such an embodiment, the pad 428 may be over a top of the substrate, the vertical trace 425 may be formed along a sidewall of a slot through the substrate, and the pad 429 may be under a bottom of the substrate.

Referring now to FIG. 4D, a perspective view illustration of a vertical trace 425 with a pad 428 at a top of the vertical trace 425 and a pad 429 at a bottom of the vertical trace 425 is shown, in accordance with an additional embodiment. In an embodiment, the vertical trace 425 is shown without the surrounding substrate and/or plug for clarity. As shown, the vertical trace 425 may have a rectangular cross-section in a direction orthogonal to the vertical direction of FIG. 4D. That is, adjacent surfaces of the vertical trace 425 may be orthogonal to each other. With the exception of the cross-sectional shape of the vertical trace 425, the structure in FIG. 4D may be similar to the structure described above with respect to FIG. 4C. For example, the pads 428, 429, and the vertical trace 425 may form a C-shaped structure around a portion of the substrate.

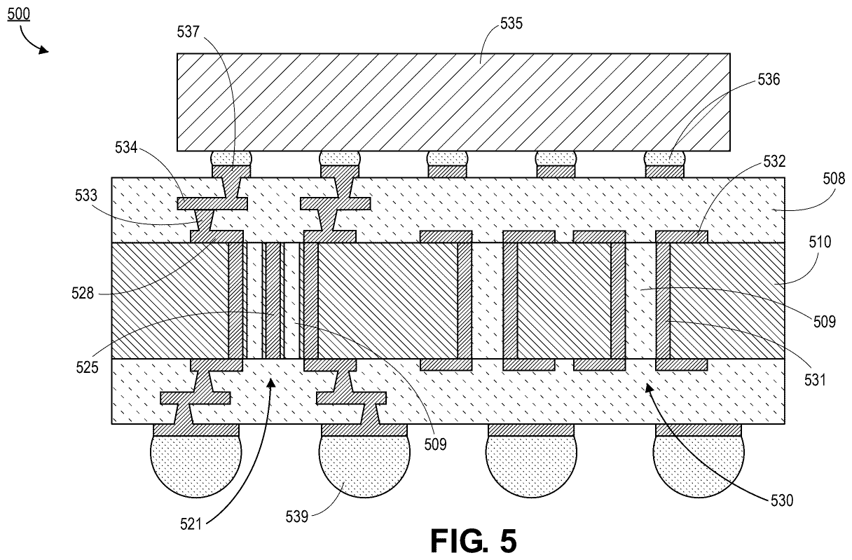

Referring now to FIG. 5, a cross-sectional illustration of an electronic package 500 is shown, in accordance with an embodiment. In an embodiment, the electronic package 500 may include a core substrate 510 with buildup layers 508 above and/or below the core substrate 510. In an embodiment, the core substrate 510 may be similar to the substrate 110 described in greater detail herein. For example, the core substrate 510 may be a glass fiber reinforced organic substrate, or the core substrate 510 may be a glass substrate.

As shown, traditional PTH vias 530 are provided on the right side of the core substrate 510, and vertical trace vias 521 are provided on the left side of the core substrate 510. The PTH vias 530 include a plated liner 531 that is filled by a plug 509. The plated liner 531 may be electrically coupled to a pad 532, a trace, or the like.

The vertical trace vias 521 include vertical traces 525. In the illustrated embodiment, the plane of the cross-section of FIG. 5 is similar to the line 5-5′ in FIG. 1E. As such, the sidewalls of the vertical traces 525 are spaced away from the plug 509 by a portion of the core substrate 510. Though, other portions of the vertical traces 525 may be in direct contact with the plug 509, depending on the plane through which the cross-section is taken. As shown, the vertical trace vias 521 can be formed with a narrower pitch in order to provide an improved routing density. The vertical traces 525 may be electrically coupled to pads 528, traces, or the like. The combination of vertical traces 525, and pads 528 (above and below the core substrate 510) forms a C-shaped structure around a portion of the core substrate 510.

In an embodiment, the pads 528 may be electrically coupled to a die 535 that is coupled to the buildup layers 508 by an interconnect 536, such as any suitable first level interconnect (FLI). In an embodiment, the die 535 may include any type of die, such as a processor (e.g., central processing unit (CPU), graphics processing unit (GPU), XPU, or the like), a memory die, a communications die, or the like. Micro-vias 533, traces 534, pads 537, and/or the like may provide an electrically conductive path between the pads 528 and the solder interconnect 539 that is coupled to the die 535. Similarly, electrically conductive features may provide an electrically conductive path between the pads 528 at a bottom of the vertical trace vias 521 and interconnects 539 on an opposite side of the electronic package 500 from the die 535. The interconnects 539 may include any suitable type of second level interconnect (FLI), such as a solder bump, a socket, or the like. In an embodiment, the interconnects 539 may be used to electrically and/or mechanically couple the electronic package 500 to a board, such as a motherboard, a printed circuit board (PCB), or the like.

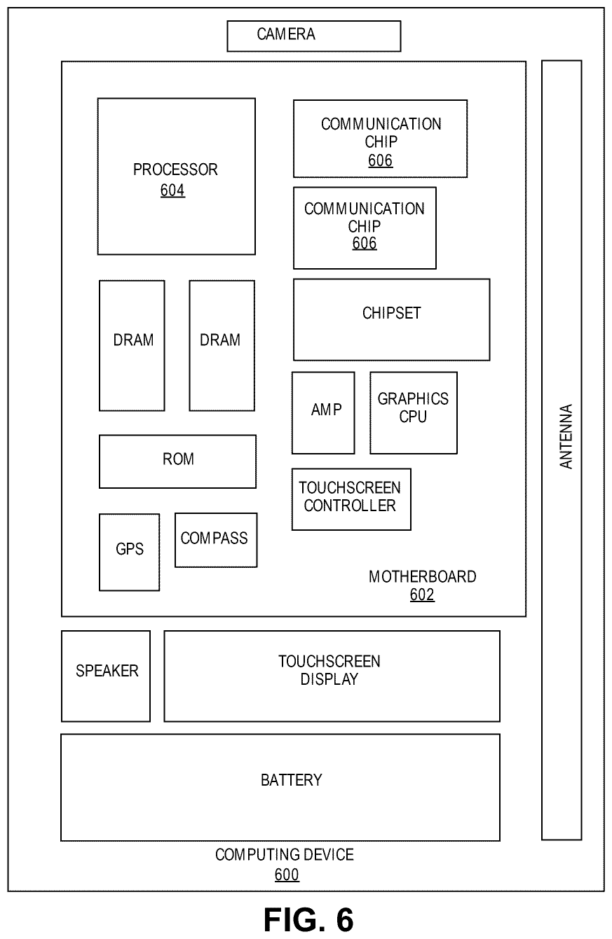

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of an electronic package that comprises a vertical trace that passes through a slot in the core of the electronic package and is surrounded by an electrically insulating plug, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of an electronic package that comprises a vertical trace that passes through a slot in the core of the electronic package and is surrounded by an electrically insulating plug, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate; a slot through the substrate, wherein a length of the slot is greater than a width of the slot; a trace on a sidewall of the slot; and a plug in the slot, wherein the plug contacts the trace and the sidewall of the slot.

Example 2: the apparatus of Example 1, wherein the plug contacts a plurality of different surfaces of the trace.

Example 3: the apparatus of Example 1 or Example 2, wherein the trace has a rectangular cross-sectional shape.

Example 4: the apparatus of Examples 1-3, wherein the trace has a trapezoidal-like cross-sectional shape.

Example 5: the apparatus of Example 4, wherein opposing non-parallel surfaces of the trace are curved.

Example 6: the apparatus of Example 5, wherein a portion of the sidewall of the slot that is adjacent to one of the opposing non-parallel surfaces of the trace is curved.

Example 7: the apparatus of Example 6, wherein the portion of the sidewall of the slot has a first radius of curvature, and wherein the one of the opposing non-parallel surfaces of the trace has a second radius of curvature that is the same as the first radius of curvature.

Example 8: the apparatus of Examples 1-7, further comprising: a second trace on the sidewall of the slot.

Example 9: the apparatus of Examples 1-8, further comprising: a pad on a top surface of the substrate, wherein the pad is electrically coupled to the trace.

Example 10: the apparatus of Example 1, wherein the substrate is a glass core or an organic core.

Example 11: an apparatus, comprising: a substrate; a slot through a thickness of the substrate, wherein the slot has a first sidewall and a second sidewall that faces the first sidewall; a plurality of first vertical traces on the first sidewall of the slot; and a plurality of second vertical traces on the second sidewall of the slot.

Example 12: the apparatus of Example 11, wherein individual ones of the plurality of first vertical traces are aligned with corresponding ones of the plurality of second vertical traces.

Example 13: the apparatus of Example 11 or Example 12, wherein the plurality of first vertical traces are mirror images of the plurality of second vertical traces.

Example 14: the apparatus of Examples 11-13, further comprising: a plug in the slot, wherein the plug contacts the plurality of first vertical traces, the plurality of second vertical traces, the first sidewall of the slot, and the second sidewall of the slot.

Example 15: the apparatus of Examples 11-14, wherein the plurality of first vertical traces and the plurality of second vertical traces have trapezoidal-like cross-sections.

Example 16: the apparatus of Example 15, wherein opposing non-parallel edges of the plurality of first vertical traces and the plurality of second vertical traces are curved.

Example 17: the apparatus of Examples 11-16, wherein the substrate is a glass core or an organic core.

Example 18: a method, comprising: forming a slot through a substrate; forming an electrically conductive liner on a surface of the slot; and forming a plurality of openings through the substrate, wherein the plurality of openings pass through the electrically conductive liner to define a plurality of vertical traces on the surface of the slot.

Example 19: the method of Example 18, wherein the plurality of openings comprise a plurality of holes.

Example 20: the method of Example 18 or Example 19, wherein the plurality of openings comprise a plurality of second slots, wherein the slot is oriented in a first direction and the plurality of second slots are oriented in a second direction that is substantially orthogonal to the first direction.

What is claimed is:

1. An apparatus, comprising:
a substrate;
a slot through the substrate, wherein a length of the slot is greater than a width of the slot;
a trace on a sidewall of the slot; and
a plug in the slot, wherein the plug contacts the trace and the sidewall of the slot.

2. The apparatus of claim 1, wherein the plug contacts a plurality of different surfaces of the trace.

3. The apparatus of claim 1, wherein the trace has a rectangular cross-sectional shape.

4. The apparatus of claim 1, wherein the trace has a trapezoidal-like cross-sectional shape.

5. The apparatus of claim 4, wherein opposing non-parallel surfaces of the trace are curved.

6. The apparatus of claim 5, wherein a portion of the sidewall of the slot that is adjacent to one of the opposing non-parallel surfaces of the trace is curved.

7. The apparatus of claim 6, wherein the portion of the sidewall of the slot has a first radius of curvature, and wherein the one of the opposing non-parallel surfaces of the trace has a second radius of curvature that is the same as the first radius of curvature.

8. The apparatus of claim 1, further comprising:
a second trace on the sidewall of the slot.

9. The apparatus of claim 1, further comprising:
a pad on a top surface of the substrate, wherein the pad is electrically coupled to the trace.

10. The apparatus of claim 1, wherein the substrate is a glass core or an organic core.

11. An apparatus, comprising:
a substrate;
a slot through a thickness of the substrate, wherein the slot has a first sidewall and a second sidewall that faces the first sidewall;
a plurality of first vertical traces on the first sidewall of the slot; and
a plurality of second vertical traces on the second sidewall of the slot.

12. The apparatus of claim 11, wherein individual ones of the plurality of first vertical traces are aligned with corresponding ones of the plurality of second vertical traces.

13. The apparatus of claim 11, wherein the plurality of first vertical traces are mirror images of the plurality of second vertical traces.

14. The apparatus of claim 11, further comprising:
a plug in the slot, wherein the plug contacts the plurality of first vertical traces, the plurality of second vertical traces, the first sidewall of the slot, and the second sidewall of the slot.

15. The apparatus of claim 11, wherein the plurality of first vertical traces and the plurality of second vertical traces have trapezoidal-like cross-sections.

16. The apparatus of claim 15, wherein opposing non-parallel edges of the plurality of first vertical traces and the plurality of second vertical traces are curved.

17. The apparatus of claim 11, wherein the substrate is a glass core or an organic core.

18. A method, comprising:
forming a slot through a substrate;
forming an electrically conductive liner on a surface of the slot; and
forming a plurality of openings through the substrate, wherein the plurality of openings pass through the electrically conductive liner to define a plurality of vertical traces on the surface of the slot.

19. The method of claim 18, wherein the plurality of openings comprise a plurality of holes.

20. The method of claim 18, wherein the plurality of openings comprise a plurality of second slots, wherein the slot is oriented in a first direction and the plurality of second slots are oriented in a second direction that is substantially orthogonal to the first direction.
